(19) United States
(12) Patent Application Publication
(10) Pub. No.: US 2022/0359160 A1
(43) Pub. Date: Nov. 10, 2022

(54) PLASMA PROCESSING APPARATUS AND PLASMA PROCESSING METHOD

(71) Applicant: Hitachi High-Tech Corporation, Minato-ku, Tokyo (JP)

(72) Inventors: Takahiro Ichikawa, Tokyo (JP); Yoshiyuki Hironaka, Tokyo (JP); Yasuo Ogoshi, Tokyo (JP)

(21) Appl. No.: 17/278,433

(22) PCT Filed: Jan. 30, 2020
(86) PCT No.: PCT/JP2020/003413

§ 371 Date: Mar. 22, 2021

(51) Int. Cl. H01J 37/32

(52) U.S. Cl. CPC H01J 37/32183; H01J 37/32146; H01J 37/32211; H01J 2237/334

(57) ABSTRACT

One plasma processing apparatus according to the invention includes: a processing chamber in which a sample is subjected to plasma processing; a first radio frequency power supply configured to supply a first radio frequency power for generating plasma via a matching unit; a sample stage on which the sample is placed; a second radio frequency power supply configured to supply a second radio frequency power to the sample stage; and a control device configured to control a matching unit so as to perform matching during a period corresponding to a mode in which a requirement for matching by the matching unit is defined when the first radio frequency power is modulated by a waveform having a plurality of amplitude values and repeating periodically. The period is each period of the waveform corresponding to any one of the plurality of amplitude values.

### TECHNICAL FIELD

The present invention relates to a plasma processing apparatus and a plasma processing method.

### BACKGROUND ART

In the related art, various plasma processing techniques have been proposed with high miniaturization and high integration of semiconductor devices. As one of the techniques, a plasma etching processing of turning ON and OFF the supply power of a radio frequency power supply in a pulsed manner at a cycle of 5 Hz to 2100 Hz is known.

For example, PTL 1 discloses a “plasma etching processing for amorphizing a deposited film by changing the supply power level in a high speed cycle”.

### CITATION LIST

### Patent Literature

PTL 1: JP-A-2014-22482

### SUMMARY OF INVENTION

### Technical Problem

In the plasma processing, it is preferable that the supply power of the radio frequency power supply is efficiently supplied to a load (hereinafter referred to as a “plasma load”) of plasma, a sample, or the like. For this purpose, it is necessary to match the impedance between the radio frequency power supply and the plasma load as much as possible.

However, as in PTL 1, in a case (for example, a case where a plurality of levels of output at 70 microseconds to 200 milliseconds is repeated at a cycle of 5 Hz to 2100 Hz) where the supply power is changed at a high speed cycle, there is a problem that the impedance of the plasma load fluctuates at a high speed due to the rapid change in the supply power.

Generally, the impedance value of a matching unit in the plasma processing apparatus is changed by mechanical control. In such a case, it may be technically difficult to perform impedance matching in accordance with a high speed impedance fluctuation.

Further, when the impedance is not sufficiently matched, power waves are reflected from the plasma load toward the radio frequency power supply. The output level of the radio frequency power supply fluctuates due to the superimposition of the reflected wave power. When the reflected wave power exceeds an allowable range and becomes a disturbance, it may be technically difficult to stabilize the output level of the radio frequency power supply to a desired value.

Accordingly, an object of the invention is to provide a technique for reducing the influence of impedance mismatching between a radio frequency power supply and a plasma load in a plasma processing.

### Solution to Problem

In order to solve the problems, one typical plasma processing apparatus according to the invention includes: a processing chamber in which a sample is subjected to plasma processing; a first radio frequency power supply configured to supply a first radio frequency power for generating plasma via a matching unit; a sample stage on which the sample is placed; a second radio frequency power supply configured to supply a second radio frequency power to the sample stage; and a control device configured to control a matching unit so as to perform matching during a period corresponding to a mode in which a requirement for matching by the matching unit is defined when the first radio frequency power is modulated by a waveform having a plurality of amplitude values and repeating periodically. The period is each period of the waveform corresponding to any one of the plurality of amplitude values.

### Advantageous Effect

In the invention, it is possible to reduce the influence of the impedance mismatching between the radio frequency power supply and the plasma load in the plasma processing.

Problems, configurations, and effects other than those described above will become apparent based on the following description of the embodiments.

### BRIEF DESCRIPTION OF DRAWINGS

FIG. 1 is a diagram showing a configuration according to a first embodiment.

FIG. 2 is a diagram showing an example of output setting of a radio frequency power supply.

FIG. 3 is a diagram showing a plurality of modes that can be set in a matching unit.

FIG. 4 is a flowchart showing automatic selection of a mode by a control device 207.

### DESCRIPTION OF EMBODIMENTS

Embodiments of the invention will be described below with reference to the drawings.

### First Embodiment

### Configuration of First Embodiment

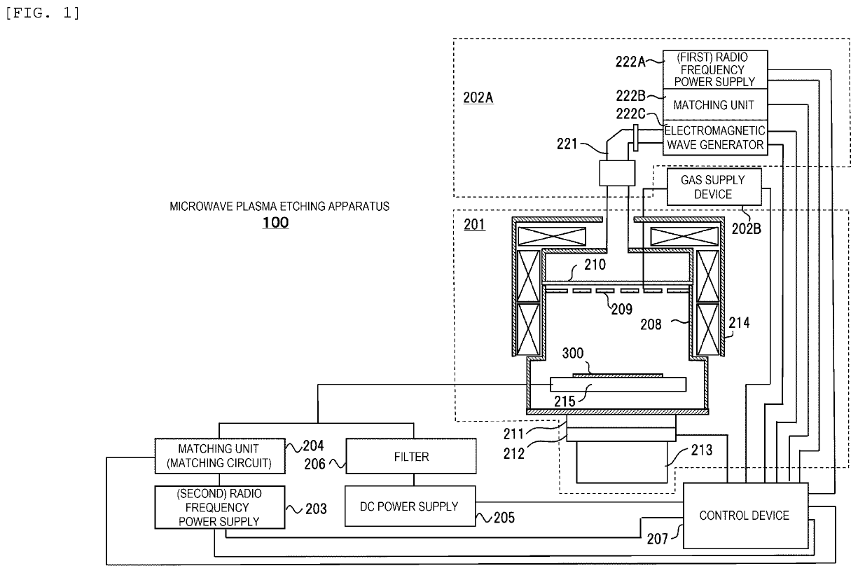

FIG. 1 is a diagram showing a configuration of an electron cyclotron resonance (ECR) type microwave plasma etching apparatus 100 as a plasma processing apparatus according to a first embodiment.

In FIG. 1, the microwave plasma etching apparatus 100 includes a processing chamber 201, an electromagnetic wave supply unit 202A, a gas supply device 202B, a radio frequency power supply 203, a matching unit 204, a DC power supply 205, a filter 206, and a control device 207.

The processing chamber 201 includes a vacuum vessel 208 that maintains a predetermined degree of vacuum, a shower plate 209 that causes an etching gas to be introduced into the vacuum vessel 208, a dielectric window 210 that causes the vacuum vessel 208 to be sealed, an exhaust opening and closing valve 211 that exhausts the vacuum vessel 208, an exhaust speed variable valve 212, a vacuum exhaust device 213 that performs exhausting via the exhaust speed variable valve 212, a magnetic field generating coil 214 that forms a magnetic field from the outside of the processing chamber 201, and a sample placing electrode 215 that causes a wafer 300 (sample) to be placed at a position facing the shower plate 209.

The gas supply device 202B supplies the etching gas into the processing chamber 201 via the shower plate 209.

The electromagnetic wave supply unit 202A includes a waveguide 221 that performs irradiating with electromagnetic waves from the dielectric window 210 into the processing chamber 201 and a radio frequency power supply 222A (a first radio frequency power supply) that supplies a first radio frequency power for generating plasma to an electromagnetic wave generator 222C via a matching unit 222B. The control device 207 controls the radio frequency power supply 222A, the matching unit 222B, and the electromagnetic wave generator 222C to modulate electromagnetic waves output by the electromagnetic wave generator 222C in a pulsed manner. In the first embodiment, an electromagnetic wave of a microwave of, for example, 2.45 GHz is used.

The electromagnetic waves with which the processing chamber 201 is irradiated via the waveguide 221 act on the magnetic field of the magnetic field generating coil 214 to ionize the etching gas in the processing chamber 201. High density plasma is generated by this ionizing action.

In the sample placing electrode 215 provided on the sample stage on which the wafer 300 is placed, the electrode surface is covered with a sprayed film, and a DC power supply 205 is connected to the sample placing electrode 215 via the filter 206.

Further, the radio frequency power supply 203 (a second radio frequency power supply) is connected to the sample placing electrode 215 via the matching unit 204. The fundamental frequency of the radio frequency power supply 203 is, for example, 400 kHz. The matching unit 204 changes the impedance between the radio frequency power supply 203 and the sample placing electrode 215.

The control device 207 controls the output level of the supply power of the radio frequency power supply 203 in accordance with a preset etching parameter. By controlling the output level, the radio frequency power supply 203 switches the output level of the supply power in a predetermined cycle pattern and outputs the switched output level. The output supply power acts on a plasma load of the plasma, wafer 300, or the like via the matching unit 204 and the sample placing electrode 215.

Further, the control device 207 switches the mode setting of the matching unit 204 based on the setting of the cycle pattern of the supply power. The relation between the cycle pattern of the supply power and the mode setting of the matching unit 204 will be described later.

In this way, the power applied to the sample placing electrode 215 acts on the plasma etching gas and the wafer 300, and performs a dry etching processing on the wafer 300.

The shower plate 209, the sample placing electrode 215, the magnetic field generating coil 214, the exhaust opening and closing valve 211, the exhaust speed variable valve 212, and the wafer 300 are axisymmetrically arranged with respect to the central axis of the processing chamber 201. Therefore, radicals and ions generated by the flow of the etching gas and the plasma, and the reaction product generated by the etching are coaxially introduced and exhausted to the wafer 300. This axisymmetric flow has an effect of improving the etching rate and the uniformity of the etching shape on the wafer surface.

### <Output Setting of Radio Frequency Power Supply 203>

Next, the cycle pattern of the supply power described above will be described.

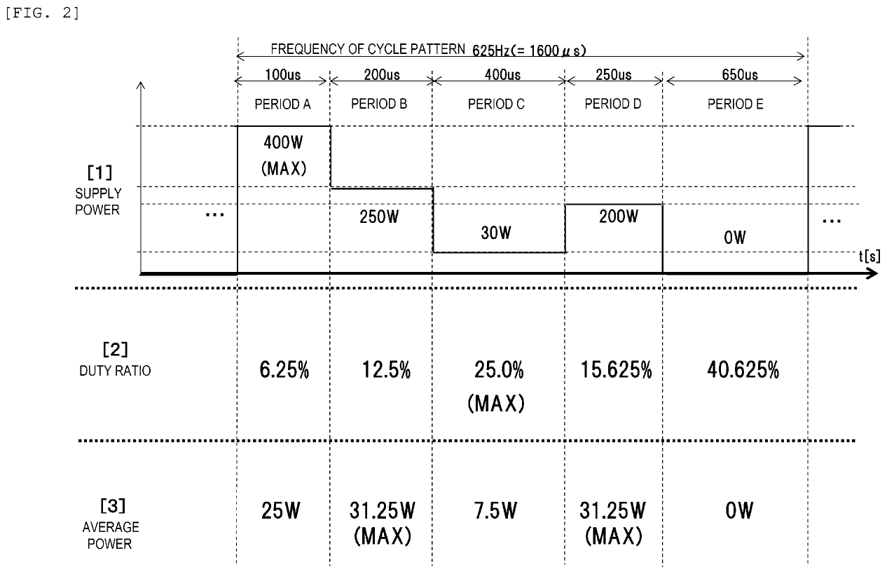

FIG. 2 is a diagram showing an example of output setting of the radio frequency power supply 203.

An upper part [1] in FIG. 2 shows an example of the cycle pattern of the supply power output from the radio frequency power supply 203. In this cycle pattern, the next periods A to E are repeated at a frequency of 625 Hz (the repetition period is 1600 microseconds).

Period A: Supply power 400 W is output to the plasma load in a period of 100 microseconds.

Period B: Supply power 250 W is output in a period of 200 microseconds.

Period C: Supply power 30 W is output in a period of 400 microseconds.

Period D: Supply power 200 W is output in a period of 250 microseconds.

Period E: An off period of 650 microseconds

In this cycle pattern, among the periods A to E, the period A is a period in which the output level of the supply power is large.

A middle part [2] in FIG. 2 shows the result of calculating the duty ratio of each of the periods A to E in one cycle of this cycle pattern based on the following Equation (1).

Duty ratio (%)=output time of supply power (seconds)÷repetition period (seconds)×100 (1)

In this cycle pattern, among the periods A to E, the period C is a period in which the duty ratio of the supply power is large. In the period E, since the supply power is off, the duty ratio of the supply power is not calculated.

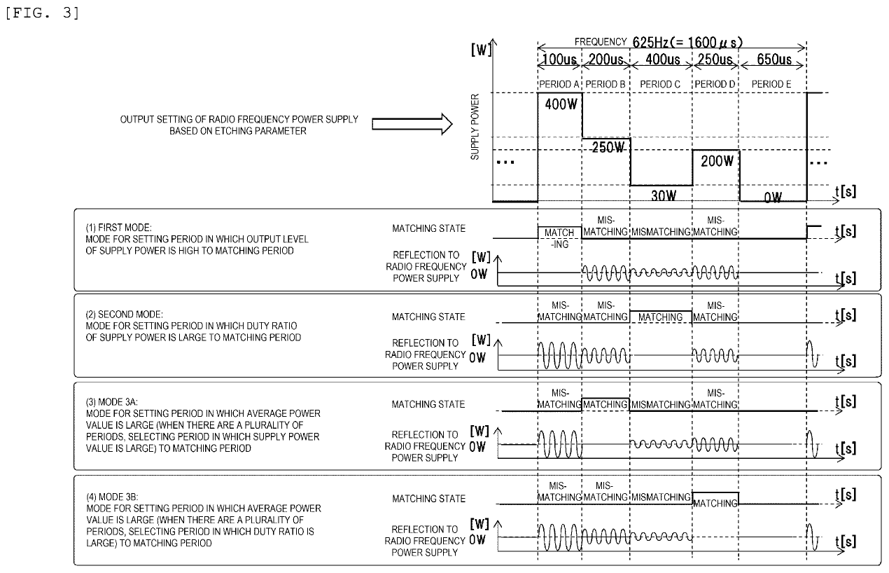

Further, the lower part [3] in FIG. 3 shows the result of calculating the average power per second based on the following Equation (2).

Average power (W)=setting value (W) of supply power×output time (seconds)×frequency (Hz) (2)

In this cycle pattern, among the periods A to E, the average power is the maximum and approximately equal in the period B and the period D. Therefore, a period candidate when the average power level is high is the period B and the period D.

### <Mode Setting of Matching Unit 204>

Next, the mode setting of the matching unit 204 will be described.

FIG. 3 is a diagram showing a plurality of modes that can be set in the matching unit 204.

The individual modes will be described below in order with reference to FIG. 3.

(1) A first mode is a mode for defining a period in which the impedance matching is performed based on a value of a modulated radio frequency power. For example, the first mode is a mode in which the impedance matching is performed in a period (for example, a period when the output level is the highest) when the output level of the supply power is high.

In the first mode shown in FIG. 3, the matching unit 204 performs the impedance matching in the period A in which the output level of the supply power is high. In the other periods B to D, since the impedances do not match, the reflected wave power is generated from the plasma load toward the radio frequency power supply 203. However, since large reflected wave power does not occur in the period A in which the output level of the supply power is high, the peak value of the reflected wave power is kept low. By this action, the first mode reduces the influence of the impedance mismatching.

(2) A second mode is a mode for defining a period in which the impedance matching is performed based on the duty ratio of the modulated radio frequency power. For example, the second mode is a mode in which the impedance matching is performed in a period (for example, a period when the output time is the longest) when the duty ratio of the supply power is large.

In the second mode shown in FIG. 3, the matching unit 204 performs the impedance matching in the period C in which the duty ratio of the supply power is large. In the other periods A, B, and D, since the impedances do not match, the reflected wave power is generated from the plasma load toward the radio frequency power supply 203. However, since no reflected wave power is generated in the period C in which the output time is long, the time when an influence of the reflected wave power is present is kept short. By this action, the second mode reduces the influence of the impedance mismatching.

(3) A mode 3A is a mode for defining a period in which the impedance matching is performed based on an average radio frequency power value which is a product of the modulated radio frequency power and the duty ratio in the period. For example, the mode 3A is a mode in which the impedance matching is performed in a period (for example, a period in which the average output level is the highest) when the output level of the average power is high.

When there are a plurality of period candidates in which the output level of the average power is high, the impedance matching is performed in the period in which the output level of the supply power is high within the period candidates.

In the mode 3A shown in FIG. 3, the matching unit 204 performs the impedance matching in the period B in which the output level of the supply power is high within the periods B and D in which the output level of the average power is high. In the other periods A, C, and D, since the impedances do not match, the reflected wave power is generated from the plasma load toward the radio frequency power supply 203.

However, a large reflected wave power is not generated in the period B in which the output level of the average power is high and the output level of the supply power is high. Therefore, the average power and the peak value of the reflected wave power are kept low. By this action, the mode 3A reduces the influence of the impedance mismatching.

(4) A mode 3B is a mode for defining a period in which the impedance matching is performed based on an average radio frequency power value which is a product of the modulated radio frequency power and the duty ratio in the period. For example, the mode 3B is a mode in which the impedance matching is performed in a period (for example, a period in which the average output level is the highest) in which the output level of the average power is high.

When there are a plurality of period candidates in which the output level of the average power is high, the impedance matching is performed in the period in which the duty ratio of the supply power is high within the period candidates.

In the mode 3B shown in FIG. 3, the matching unit 204 performs the impedance matching in the period D in which the duty ratio of the supply power is large within the periods B and D in which the output level of the average power is high. In the other periods A to C, since the impedances do not match, the reflected wave power is generated from the plasma load toward the radio frequency power supply 203.

However, a large reflected wave power does not occur in the period D in which the output level of the average power is high and the duty ratio of the supply power is large. Therefore, the average power of the reflected wave power and the time when an influence of the reflected wave power is present are kept low. By this action, the mode 3B reduces the influence of the impedance mismatching.

(5) Regarding a third mode, when there is only one period candidate in which the output level of the average power is high, the periods of matching in the mode 3A and the mode 3B are equal. In this case, since there is no difference in operation between the mode 3A and the mode 3B, both of the mode 3A and the mode 3B can be treated as the third mode.

That is, the third mode is a mode for defining a period in which the impedance matching is performed based on an average radio frequency power value which is a product of the modulated radio frequency power and the duty ratio in the period. For example, the third mode is a mode in which the impedance matching is performed in a period (for example, a period in which the average output level is the highest) in which the output level of the average power is high.

Therefore, the average power of the reflected wave power and the time when an influence of the reflected wave power is present are kept low. By this action, the mode 3 reduces the influence of the impedance mismatching.

### <Operation of Control Device 207>

Next, the operation of control device 207 will be described.

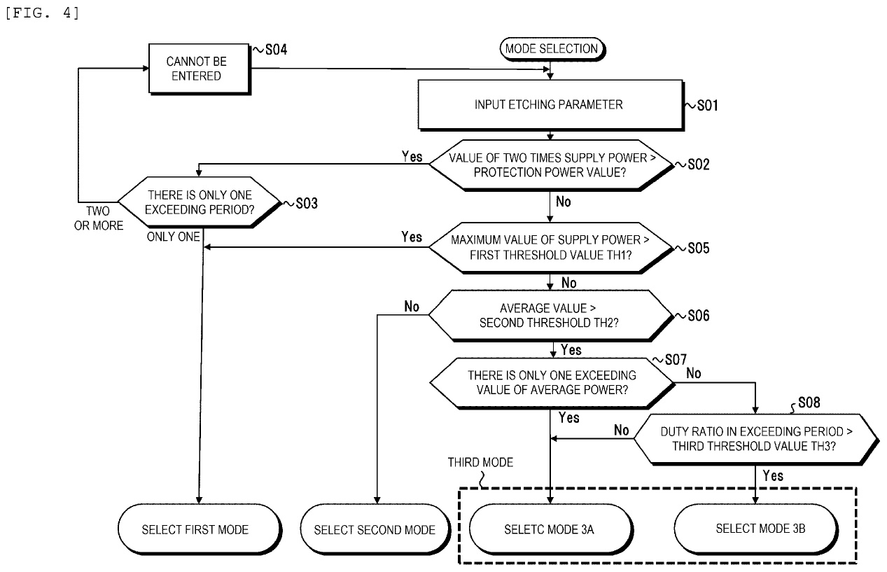

FIG. 4 is a flowchart showing automatic selection of a mode by the control device 207.

Here, the order of the step numbers shown in FIG. 4 will be described.

Step S01: the control device 207 acquires an etching parameter set in the microwave plasma etching apparatus 100. In accordance with this etching parameter, the control device 207 determines a cycle pattern (for example, see FIG. 2) of the supply power whose output is set to the radio frequency power supply 203.

Step S02: when the impedance is mismatched between the radio frequency power supply 203 and the plasma load, the reflected wave power returning from the plasma load to the radio frequency power supply 203 is generated for the supply power (instantaneously traveling wave power) supplied from the radio frequency power supply 203 to the plasma load. At this time, the traveling wave power and the reflected wave power interfere with each other, and a power peak at a maximum of two times is generated.

Accordingly, the control device 207 determines whether a value of two times the supply power exceeds a protection power value (absolute rating) regarding the supply power for each period in the cycle pattern. When there is “a value of two times the supply power” exceeding the protection power value, the control device 207 proceeds to step S03. Otherwise, the control device 207 proceeds to step S05.

Step S03: the control device 207 determines whether there is only one period in which the “value of two times the supply power” exceeds the protection power value.

If there is only one “exceeding period”, the control device 207 selects the first mode. If the first mode is selected, the impedance matching is performed in the “exceeding period” in which the output level of the supply power is the highest. Therefore, the reflected wave power in the “exceeding period” is prevented, and a power peak exceeding the protection power value is not generated. Since the large reflected wave power in the “exceeding period” is prevented, the influence of the impedance mismatching between the radio frequency power supply and the plasma load is reduced throughout the cycle pattern.

On the other hand, when the “exceeding period” is set to two or more, the control device 207 proceeds to step S04.

Step S04: here, there are two or more “exceeding periods”. In this case, it is possible to achieve the impedance matching in one of the “exceeding periods”. However, since the impedance is mismatched in the rest of the “exceeding periods”, the power peak exceeding the protection power value may be generated by any chance. Accordingly, the control device 207 notifies the factory management system that the current etching parameter cannot be input. Thereafter, the control device 207 returns to step S01 and waits until the etching parameter is reset.

Step S05: next, the control device 207 determines whether the maximum value of the supply power in the cycle pattern exceeds a first threshold value th1. Here, the first threshold value th1 is a threshold value for determining whether the maximum value of the supply power is prominently large in the cycle pattern, and is set to, for example, 100 W.

Here, when the maximum value of the supply power does not exceed the first threshold value th1, the control device 207 proceeds to step S06.

On the other hand, when the maximum value of the supply power exceeds the first threshold value th1, the control device 207 selects the first mode. If the first mode is selected, the impedance matching is performed in a period in which the maximum value of the supply power exceeds the first threshold value th1. Therefore, a large reflected wave power during this period is prevented. As a result, the influence of the impedance mismatching between the radio frequency power supply and the plasma load is reduced throughout the cycle pattern.

Step S06: subsequently, the control device 207 determines whether the average power for each period in the cycle pattern exceeds a second threshold value th2. Here, the second threshold value th2 is a threshold value for determining whether the average power in the period is prominently large in the entire cycle pattern, and is set to, for example, 60 W.

Here, when there is a period in which the average power exceeds the second threshold value th2, the control device 207 proceeds to step S07.

On the other hand, when there is no period in which the average power exceeds the second threshold value th2, the change in the average power in the entire cycle pattern is expected to be gentle. Accordingly, the control device 207 selects the second mode 2. If the second mode is selected, the impedance matching is performed in the period in which the duty ratio of the supply power is large, and the reflected wave power is prevented in the period in which the output time is long. Therefore, the influence of the impedance mismatching between the radio frequency power supply and the plasma load is reduced in the cycle pattern in which the change in the average power is gentle.

Step S07: next, the control device 207 determines whether there is only one value of the average power exceeding the second threshold value th2.

When there are two or more values of the average power exceeding the second threshold value th2, the control device 207 proceeds to step S08.

On the other hand, when there is one value of the average power exceeding the second threshold th2, the control device 207 selects the mode 3A. In the mode 3A, the impedance matching is performed in the period in which “the average power exceeds the second threshold value th2”. When there are a plurality of periods in which “the average power exceeds the second threshold value th2”, the impedance matching is performed in the period in which the output level of the supply power is higher within these periods.

In this case, the reflected wave power is prevented in the period in which the average power is large (and the output level of the supply power is higher). Therefore, the influence of the impedance mismatching between the radio frequency power supply and the plasma load is reduced in the cycle pattern in which the average power is partially high.

Step S08: the control device 207 calculates the duty ratio of the period in which “the average power exceeds the second threshold value th2” to the cycle pattern. The control device 207 determines whether the calculated duty ratio exceeds a third threshold value th3.

This third threshold value th3 is a threshold value for determining whether the output time in the period in which the average power is high is long or short, and is set to, for example, 31.25% (the output time is 500 microseconds).

Here, when the duty ratio in the period in which the average power is large exceeds the third threshold value th3, the control device 207 selects the mode 3B. In the mode 3B, the impedance matching is performed in the period in which the duty ratio is large within the periods in which “the average power exceeds the second threshold value th2”.

In this case, the reflected wave power is prevented in the period (the period in which the output time is long) in which the average power is large and the duty ratio is large. Therefore, the influence of the impedance mismatching between the radio frequency power supply and the plasma load is reduced in the cycle pattern in which the average power is continuously large.

On the other hand, when the duty ratio in the period in which the average power is large does not exceed the third threshold value th3, the control device 207 selects the mode 3A. In this case, the influence of the impedance mismatching between the radio frequency power supply and the plasma load is reduced in the cycle pattern in which the average power is partially high.

By the series of operations described above, the control device 207 can appropriately select the mode of the matching unit 204 in accordance with the cycle pattern set in the radio frequency power supply 203.

### Effects and the Like of First Embodiment

The first embodiment has the following effects.

(1) In the first embodiment, by selecting the first mode, the impedance matching is performed in the period in which the output level of the supply power is high. In this case, it is possible to prevent the reflected wave power generated in the period in which the output level of the supply power is high.

(2) In general, in the plasma processing, in a period, the higher the output level of the supply power, the larger the energy applied to ions, radicals, and the like is, which greatly contributes to the plasma processing. In the first mode, the impedance matching is performed in this period. Therefore, it is possible to further increase the processing efficiency of the plasma processing by reducing the energy loss of the plasma due to the impedance mismatching.

(3) In the first embodiment, by selecting the second mode, the impedance matching is performed in the period in which the duty ratio of the supply power is large. In this case, it is possible to prevent the reflected wave power generated in the period in which the duty ratio of the supply power is large.

(4) In general, in the plasma processing, in a period, the larger the duty ratio of the supply power, the larger the energy continuously applied to ions, radicals, and the like is, which greatly contributes to the plasma processing. In the second mode, the impedance matching is performed in this period. Therefore, it is possible to further increase the processing efficiency of the plasma processing by reducing the energy loss of the plasma due to the impedance mismatching.

(5) In the first embodiment, by selecting the third mode (the mode 3A and the mode 3B), the impedance matching is performed in the period in which the output level of the average power is high. Therefore, in the third mode, it is possible to prevent the reflected wave power generated in the period in which the output level of the average power is high.

(6) In general, in the plasma processing, in a period, the higher the output level of the average power, the larger the average energy applied to ions, radicals, and the like is, which greatly contributes to the plasma processing. In the third mode (the mode 3A and the mode 3B), the impedance matching is performed in this period. Therefore, it is possible to further increase the processing efficiency of the plasma processing by reducing the energy loss of the plasma due to the impedance mismatching.

(7) In the first embodiment, by selecting the mode 3A, the impedance matching is performed in the period in which the output level of the average power is high and the output level of the supply power is high. Therefore, in this mode 3A, it is possible to prevent the reflected wave power generated in the period in which both the average power and the supply power are large.

(8) In the first embodiment, by selecting the mode 3B, the impedance matching is performed in the period in which the output level of the average power is high and the duty ratio of the supply power is large. Therefore, in this mode 3B, it is possible to prevent the reflected wave power generated in the period in which both the average power and the duty ratio are large.

(9) As described above, in the first embodiment, it is possible to change the period in which the impedance matching is performed by mode selection. As a result, it is possible to select a mode that effectively reduces the influence of the impedance mismatching.

(10) In the first embodiment, it is determined whether a period is present in which the supply power exceeds the first threshold value th1. When it is determined that the period is “present”, the first mode is automatically selected. In this case, the impedance matching is performed in the period in which the supply power exceeds the first threshold value th1. Therefore, it is possible to automatically prevent the reflected wave power generated in the period in which the supply power exceeds the first threshold value th1.

(11) In the first embodiment, it is determined whether a period is present in which the average power exceeds the second threshold value th2. When it is determined that the period is “not present”, the second mode is automatically selected. In this case, in a situation where the average power in all the periods does not exceed the second threshold value th2, the impedance matching is performed in the period in which the duty ratio of the supply power is large. Therefore, it is possible to automatically prevent the reflected wave power generated in such a period.

(12) In the first embodiment, it is determined whether a period is present in which the average power exceeds the second threshold value th2 is determined. When it is determined that the period is “present”, the third mode (the mode 3A and the mode 3B) is automatically selected. In this case, the impedance matching is performed in the period in which the average power exceeds the second threshold value th2. Therefore, it is possible to automatically prevent the reflected wave power generated in such a period.

(13) In the first embodiment, it is determined how many values of the average power exceed the second threshold value. When it is determined that “only one type is present”, the mode 3A is automatically selected. In this case, the impedance matching is performed in the period in which the average power is larger than the second threshold value and the output level of the supply power is high. Therefore, it is possible to automatically prevent the reflected wave power generated in such a period.

(14) In the first embodiment, when it is determined that a plurality of values of the average power exceeding the second threshold value are present and the duty ratio in the period does not exceed the third threshold value, the mode 3A is automatically selected. In this case, the impedance matching is performed in the period in which the average power is larger than the second threshold value and the output level of the supply power is high. Therefore, it is possible to automatically prevent the reflected wave power generated in such a period.

(15) In the first embodiment, when it is determined that a plurality of values of the average power exceeding the second threshold value are present and the duty ratio of the period exceeds the third threshold value, the mode 3B is automatically selected. In this case, the impedance matching is performed in the period in which the average power is larger than the second threshold value and the duty ratio of the supply power is large. Therefore, it is possible to automatically prevent the reflected wave power generated in such a period.

Next, a second embodiment will be further described.

### Second Embodiment

### Configuration of Second Embodiment

An electron cyclotron resonance (ECR) type microwave plasma etching apparatus, which is a plasma processing apparatus according to a second embodiment, has the same configuration as that of the microwave plasma etching apparatus 100 according to the first embodiment (see FIG. 1). Accordingly, the configuration according to the second embodiment will be described with reference to the configuration description of the first embodiment and FIG. 1, and the repeated description thereof will be omitted.

### Description of Operation According to Second Embodiment

In the second embodiment, the control device 207 controls the period in which the impedance matching is performed using the matching unit 222B between the radio frequency power supply 222A and the electromagnetic wave generator 222C.

That is, the control device 207 performs the impedance matching of the matching unit 222B in a period defined by any one of the first mode, the second mode, and the third mode (the mode 3A and the mode 3B) in accordance with the modulation of the electromagnetic wave generator (radio frequency power).

The flow of the specific operation according to the second embodiment is the same as the flow of the specific operation according to the first embodiment except that the impedance matching operation target is replaced from “the (second) radio frequency power supply 203, the matching unit 204, and the sample placing electrode 215” according to the first embodiment to “the (first) radio frequency power supply 222A, the matching unit 222B, and the electromagnetic wave generator 222C”.

Accordingly, in order to simplify the description, as the description of the operation according to the second embodiment, the operation target will be changed regarding the description of the operation according to the first Embodiment and the necessary replacement will be performed accordingly, and the duplicate description here will be omitted. The specific numerical value of an operation parameter such as a threshold value can be designed by an experiment or a simulation operation.

### Effects and the Like According to Second Embodiment

In the second embodiment, the same effects as the above-described effects (1) to (15) according to the first embodiment can be attained for the first radio frequency power supply 222A.

### Supplementary Items and the Like According to Embodiments

In the first embodiment and the second embodiment, the first threshold value th1, the second threshold value th2, the third threshold value th3, and other parameters have been described. However, the invention is not limited thereto. The first threshold value th1, the second threshold value th2, the third threshold value th3, and other parameters may be set to optimum values in accordance with conditions such as gas and pressure in the plasma processing based on experiments, simulation operations, and the like.

In the first embodiment and the second embodiment, a case has been described in which an etching processing is performed as one plasma processing. However, the invention is not limited thereto. The invention can be applied to an application for reducing the influence of the impedance mismatching between a fluctuating radio frequency power supply and a plasma load in the plasma processing.

Further, in the first embodiment and the second embodiment, the impedance matching is not performed in any of the modes when the output level of the radio frequency power supply is 0 W (OFF period). Accordingly, such an OFF period may be excluded in advance from the periods in which the impedance matching is performed.

The first embodiment and the second embodiment have been described as independent embodiments. However, the first embodiment and the second embodiment may be simultaneously implemented.

The invention is not limited to the embodiments described above and includes various modifications. For example, the embodiments described above have been described in detail for easy understanding of the invention, and the invention is not necessarily limited to those including all of the configurations described above. All or part of the first embodiment and the second embodiment may be combined as appropriate. It is possible to add, remove, and replace another configuration to or from a part of the configuration according to the first embodiment and the second embodiment.

### REFERENCE SIGN LIST

100 . . . microwave plasma etching apparatus, 201 . . . processing chamber, 202A . . . electromagnetic wave supply unit, 202B . . . gas supply device, 203 . . . second radio frequency power supply, 204 . . . matching unit, 205 . . . DC power supply, 206 . . . filter, 207 . . . control unit, 208 . . . vacuum vessel, 209 . . . shower plate, 210 . . . dielectric window, 211 . . . exhaust opening and closing valve, 212 . . . exhaust speed variable valve, 213 . . . vacuum exhaust device, 214 . . . magnetic field generating coil, 215 . . . sample placing electrode (sample stage), 221 . . . waveguide, 222A . . . first radio frequency power supply, 222B . . . matching unit, 222C . . . electromagnetic wave generator, 300 . . . wafer

1. A plasma processing apparatus, comprising:
a processing chamber in which a sample is subjected to plasma processing;
a first radio frequency power supply configured to supply a first radio frequency power for generating plasma via a matching unit;
a sample stage on which the sample is placed;
a second radio frequency power supply configured to supply a second radio frequency power to the sample stage; and
a control device configured to control a matching unit so as to perform matching during a period corresponding to a mode in which a requirement for matching by the matching unit is defined when the first radio frequency power is modulated by a waveform having a plurality of amplitude values and repeating periodically, wherein
the period is each period of the waveform corresponding to any one of the plurality of amplitude values.

2. A plasma processing apparatus, comprising:
a processing chamber in which a sample is subjected to plasma processing;
a first radio frequency power supply configured to supply a first radio frequency power for generating plasma;
a sample stage on which the sample is placed;
a second radio frequency power supply configured to supply a second radio frequency power to the sample stage via a matching unit; and
a control device configured to control a matching unit so as to perform matching during a period corresponding to a mode in which a requirement for matching by the matching unit is defined when the second radio frequency power is modulated by a waveform having a plurality of amplitude values and repeating periodically, wherein
the period is each period of the waveform corresponding to any one of the plurality of amplitude values.

3. The plasma processing apparatus according to claim 1, wherein
the mode includes a first mode in which a requirement for matching is defined based on a value of the modulated radio frequency power.

4. The plasma processing apparatus according to claim 1, wherein
the mode includes a second mode in which a requirement for matching is defined based on a duty ratio of the modulated radio frequency power.

5. The plasma processing apparatus according to claim 1, wherein
the mode further includes a third mode in which a requirement for matching is defined based on an average radio frequency power value which is a product of the modulated radio frequency power and a duty ratio in the period.

6. The plasma processing apparatus according to claim 5, wherein
the third mode further includes, when there are a plurality of period candidates corresponding to the third mode, a mode 3A in which a requirement is defined based on a value of the modulated radio frequency power and a mode 3B in which a requirement is defined based on the duty ratio.

7. A plasma processing method for processing a sample using plasma generated by a radio frequency power that is modulated by a waveform having a plurality of amplitude values and repeating periodically and that is supplied via a matching unit, wherein
matching is performed during a period corresponding to a mode in which a requirement for the matching by the matching unit is defined, and
the period is each period of the waveform corresponding to any one of the plurality of amplitude values.

8. A plasma processing method for plasma processing a sample while supplying, via a matching unit, a radio frequency power modulated by a waveform having a plurality of amplitude values and repeating periodically to a sample stage on which the sample is placed, wherein
matching is performed during a period corresponding to a mode in which a requirement for the matching by the matching unit is defined; and
the period is each period of the waveform corresponding to any one of the plurality of amplitude values.
